(19) United States
(12) Patent Application Publication
(10) Pub. No.: US 2006/0270225 A1
(43) Pub. Date: Nov. 30, 2006

(54) Silicon carbide semiconductor device fabrication method

(75) Inventors: Jun Kawai, Anjo-shi (JP); Tsuyoshi Yamamoto, Kariya-shi (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/436,593

(22) Filed: May 19, 2006

(30) Foreign Application Priority Data
May 26, 2005 (JP) 2005-154266

(51) Int. Cl. H01L 21/44; H01L 23/48

(52) U.S. Cl. 438/682; 257/766

(57) ABSTRACT

In a SiC semiconductor device fabrication method, on fabricating a SiC semiconductor device, a graphite layer formed on a Ni silicide film is eliminated by sputtering, oxidation, reduction, or evaporation of heating. A wiring electrode is then formed on the Ni silicide on which no graphite layer is formed. This increases adhesion force between the wiring electrode and the Ni silicide film on the SiC substrate, and thereby prevents that the wiring electrode peels off from the Ni silicide film on the SiC substrate.

### CROSS-REFERENCE TO RELATED APPLICATIONS

This application is related to and claims priority from Japanese Patent Application No. 2005-154266 filed on May 26, 2005, the contents of which are hereby incorporated by reference.

### BACKGROUND OF THE INVENTION

1. Field of the Invention

The present invention relates generally to a method of fabricating a silicon carbide (SiC) semiconductor device capable of having an Ohmic contact made of silicon carbide.

2. Description of the Related Art

A prior art technique disclosed a method of fabricating a silicon carbide (SiC) semiconductor device having Ohmic electrodes. The fabrication method includes the salicide process of performing vacuum evaporation of nickel (Ni) on a silicon carbide (SiC) formed on a Si substrate or a wafer, and performing thermal treatment for the substrate in order to form a Ni suicide film on the SiC substrate. For example, see a prior art document, Imai et al., “N-type and p-type ohmic contacts for 4H—SiC using Ni salicide process”, 29p-ZM-14, the 51-th Japanese applied physics conference proceeding, March, 2004.

However, the conventional technique involves a following drawback. On performing thermal treatment of Ni on the surface of the SiC substrate in order to form a Ni silicide film, graphite layer is simultaneously formed on the surface of the Ni siliside film. If a wiring electrode is then formed on the graphite layer on the Ni silicide film, the presence of the graphite layer decreases adhesion between the wiring electrode and the Ni silicide film. As a result, the wiring electrode peels off from the surface of the Ni silicide layer.

### SUMMARY OF THE INVENTION

It is an object of the present invention to provide an improved silicon carbide (SiC) semiconductor device fabrication method capable of eliminating a graphite layer from the surface of a Ni silicide film, and having a high adhesion capability between the Ni silicide film and the wiring electrode formed thereon.

To achieve the above-purposes, the present invention provides a SiC semiconductor device fabrication method having following steps. A nickel (Ni) film is formed on a surface of a SiC substrate. A Ni silicide film is formed on the SiC substrate by thermal treatment. A graphite layer is formed on a surface of the Ni silicide film during the thermal treatment. A graphite layer is eliminated from the surface of the Ni silicide film. A wiring electrode is formed on the Ni silicide film from which the graphite layer has been eliminated.

The present invention provides the improved method in which the wiring electrode is formed on the Ni silicide film after the graphite layer has been eliminated from the surface of the Ni silicide film. Therefore the method of the present invention prevents the deterioration of adhesion force between the Ni silicide film and the wiring electrode, and also prevents that the wiring electrode peels off from the surface of the Ni silicide film formed on the SiC substrate of the SiC semiconductor device.

### BRIEF DESCRIPTION OF THE DRAWINGS

A preferred, non-limiting embodiment of the present invention will be described by way of example with reference to the accompanying drawings, in which:

FIG. 1 is a schematic diagram showing a configuration of a wiring electrode forming apparatus for use in a SiC semiconductor device fabrication method according to a first embodiment of the present invention;

FIGS. 2A to 2E are sectional diagrams of the SiC semiconductor device in fabrication steps of the SiC semiconductor device fabrication method according to the present invention;

FIG. 3 is a flow chart showing the fabrication process of the SiC semiconductor device of the first embodiment;

FIG. 4 is a flow chart showing a fabrication process of the SiC semiconductor device of a second embodiment of the present invention;

FIG. 5 is a schematic diagram showing a configuration of an electrode forming apparatus for use in a SiC semiconductor device fabrication method according to a third embodiment of the present invention; and

FIG. 6 is a flow chart showing a fabrication process of the SiC semiconductor device of the third embodiment.

### DETAILED DESCRIPTION OF THE PREFERRED EMBODIMENTS

Hereinafter, various embodiments of the present invention will be described with reference to the accompanying drawings. In the following description of the various embodiments, like reference characters or numerals designate like or equivalent component parts throughout the several diagrams.

### First Embodiment

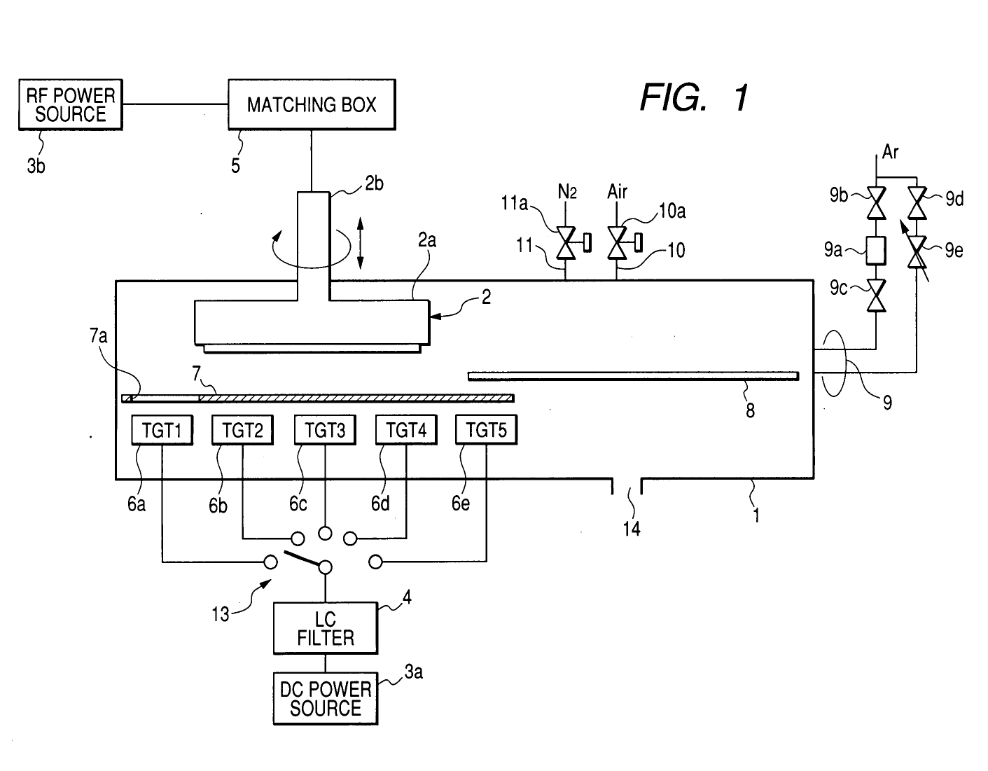

FIG. 1 is a schematic diagram showing a configuration of a wiring electrode forming apparatus for use in a SiC semiconductor device fabrication method according to the first embodiment of the present invention.

FIG. 1 shows a sputter device as the electrode forming apparatus having a chamber 1, a substrate holder 2, a DC power source 3a, a RF power source 3b, an inductive filter or a LC filter 4, a matching box 5, a target metal electrodes 6a to 6e, a rotatable shutter 7, a slidable shutter 8, an argon (Ar) gas inlet 9, an air inlet 10, and a nitrogen (N₂) gas inlet 11.

The chamber 1 accommodates a part of the substrate holder 2, each of the target metal electrodes 6a to 6e, the rotatable shutter 7, and the slidable shutter 8. The argon gas inlet 9, the air inlet 10, and the nitrogen gas inlet 11 are joined to the chamber 1, through which those gases are introduced into the chamber 1.

The substrate holder 2 has a rotatable disk 2a and a central axis 2b thereof. The chamber 1 accommodates the rotatable disk 2a and a part of the central axis 2b as shown in FIG. 1.

The rotatable disk 2a rotates by the central axis 2b and moves up and down in a vertical line.

A silicon carbide (SiC) layer formed on a Si substrate (hereinafter, will be referred to as “a SiC substrate instead of “a SiC layer formed on a Si substrate”) is mounted on the rotatable disk 2a of the substrate holder 2. A SiC semiconductor device will be formed on the SiC substrate.

The LC filter 4 adjusts a capacitance therein so that the DC power source 3a supplies optimum electrical power to the target metal electrodes 6a to 6e for performing sputtering, namely, for performing a stable discharge between the target metal electrodes 6a to 6e and the substrate holder 2 during the sputtering.

A switch 13 is placed between the target metal electrodes 6a to 6e and the LC filter 4. The switch 13 selects one of the target metal electrodes 6a to 6e. The DC power source 3a supplies the electrical power to the selected target metal electrode.

The target metal electrodes 6a to 6e are applied to electrode materials, respectively, or they are made of electrode materials, respectively. For example, it is possible to use Titanium (Ti), Nickel (Ni), and Gold (Au) as the electrode materials.

During the sputtering, the electrode material applied to or forming the target electrode selected by the switch 13 will be sputtered and formed on the SiC semiconductor device. FIG. 1 shows five kinds of electrode materials applied to the target metal electrodes 6a to 6e, respectively. However, the present invention is not limited by this configuration. It is acceptable that the electrode materials are applied to some necessary target metal electrodes.

The rotatable shutter 7 has an opening 7a and rotates freely. The desired metal electrode selected in all of the target metal electrodes 6a to 6e is exposed through the opening 7a in the rotatable shutter 7 during the sputtering.

The slidable shutter 8 is configured to slide between the substrate holder 2 and the target metal electrodes 6a to 6e in the chamber 1 so that the substrate holder 2 and the target metal electrodes 6a to 6e face to each other and close up the space between them.

The argon gas inlet 9 introduces argon gas as inactive gas into the chamber 1. The argon gas inlet 9 is equipped with a mass flow controller 9a and a plurality of valves 9b to 9e that are configured to control the amount of argon gas flow, for example, 30 sccm (standard cc/min) and 0.6 Pa.

The air inlet 10 and the nitrogen gas inlet 11 introduce air and nitrogen into the chamber 1, respectively. The air inlet 10 and the nitrogen gas inlet 11 are equipped with valves 10a and 11a, respectively, in order to control the amount of air and nitrogen to be introduced into the chamber 1 and to stop the introduction of those gases.

The chamber 1 is equipped with an exhaust outlet 14 in order to keep the pressure of the chamber constant by controlling the amount of exhaust gas to the outside of the chamber 1.

Next, a description will now be given of the fabrication method of the SiC semiconductor device of the first embodiment.

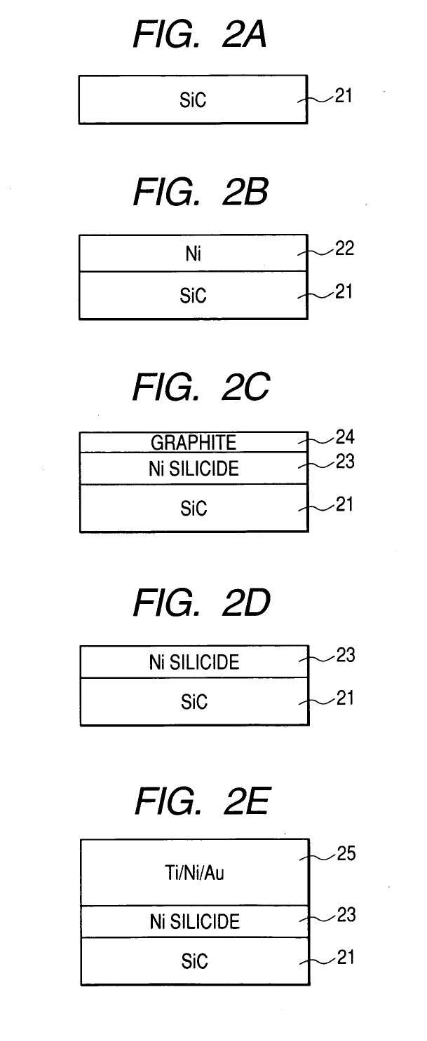

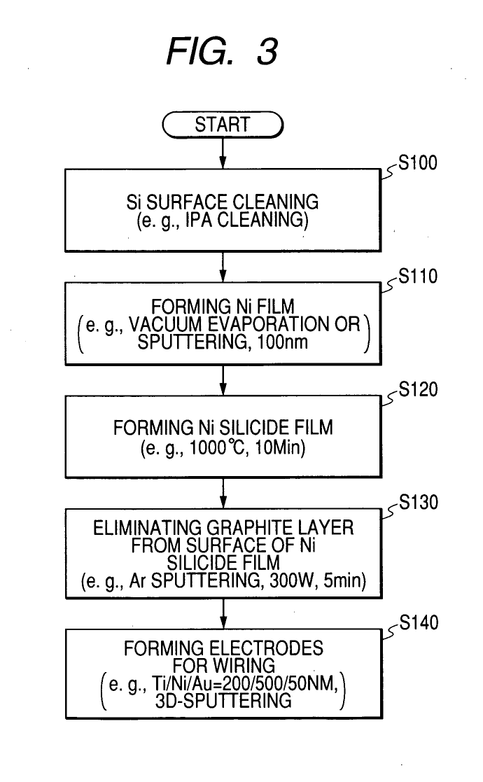

FIGS. 2A to 2E are sectional diagrams of the SiC semiconductor device in fabrication steps of the SiC semiconductor device fabrication method according to the present invention. FIG. 3 is a flow chart showing the fabrication process of the SiC semiconductor device of the first embodiment.

First, a SiC 21 substrate such as a substrate including 4H—SiC is prepared, as shown in FIG. 2A. It is acceptable that the SiC substrate 21 is made up of only SiC substrate or SiC formed on another kind of substrate.

The surface of the SiC 21 is cleaned with isopropyl alcohol. (step S100 shown in FIG. 3)

Following, a Ni film 22 of 100 nm is formed on the surface of the SiC substrate 21, as shown in FIG. 2B. (step S110 shown in FIG. 3)

In a concrete example, the Ni film 22 is formed by vacuum evaporation manner or sputtering manner. On performing the sputtering, it is possible to use the electrode forming apparatus as shown in FIG. 1.

Following, the SiC 21 substrate on which the Ni film 22 is formed is taken from the sputtering apparatus, for example.

Thermal treatment is performed for the SiC 21 substrate in order to perform salicide process by which the Ni film 22 becomes a silicide Ni film. In a concrete example, the thermal treatment is performed in more than 900° C., for example, at 1,000° C. for 10 minutes.

The thermal treatment produces the Ni silicide film 23 and a graphite layer 24 on the Ni silicide film 23, as shown in FIG. 2C.

Next, the SiC substrate having the Ni silicide film 23 is fixed onto the surface of the substrate holder 2 in the chamber 1.

The argon gas sputtering is then performed in order to eliminate the graphite layer 24 formed on the surface of the Ni silicide film 23. (step S130 shown in FIG. 3)

In a concrete example, argon gas is introduced into the chamber 1 through the argon gas inlet 9 so that the flow rate of argon gas is kept at a specified value, for example, 30 sccm (standard cc/min) and 0.6 Pa. Further, the amount of exhaust gas through the exhaust gas outlet 14 is controlled, and the introduction of air and nitrogen through the air inlet 10 and the nitrogen gas inlet 11 is halted in order to vacuum the chamber 1 filled with argon gas. Further, the rotatable shutter 7 or the slidable shutter 8 cover the desired target metal electrodes 6a to 6e according to necessity. By starting-up the RF power source 3b, the rotatable disk 2a of the substrate holder 2 rotates by the central axis 2b. When the RF power source 3b provides the desired electrical power (for example, 300 W), electrical discharging occurs between the substrate holder 2 and the target metal electrodes 6a to 6e through the opening 7a.

Argon particles fly to and collides with the surface of the graphite layer 24 formed on the SiC substrate 21 fixed to the substrate holder 2. Sputtering is performed for five minutes or more in order to remove the graphite layer 24 completely from the surface of the Ni silicide film 23 on the SiC substrate 21.

Following, while maintaining the SiC substrate in the chamber 1 and keeping the vacuum state of the chamber 1, the wiring formation process is performed in order to form wiring electrode 25 on the surface of the Ni silicide film 23. (step S140 shown in FIG. 3)

As a result, as shown in FIG. 2E, the wiring electrode 25 is formed on the surface of the Ni silicide film 23.

In a concrete example, the DC power source 3a starts up and switch 13 selects one or more desired target metal electrode 6a to 6e so as to electrically connect the selected electrode to the LC filter 4. The desired target metal electrode selected is exposed to the substrate holder 2 through the opening 7a of the rotatable shutter 7. The sputtering is then performed under the above condition. When the wiring electrode 25 is formed in a three-layer laminating structure, Ti/Ni/Au (Ti is 200 nm thickness, Ni is 500 nm thickness, and Au is 50 nm thickness), the switch 13 selects the target metal electrode three times every obtaining a desired thickness of each wiring electrode layer. This manner is called to as 3D (three dimension) sputtering in which the switch 13 switches the target metal electrodes 6a to 6e connected to the LC filter 4.

Following fabrication processes such as forming an insulating film between layers, performing wire bonding, and soldering are omitted here. The fabrication process of the SiC semiconductor device is thereby completed.

As described above, according to the SiC semiconductor device fabrication method of the first embodiment, it is possible to form the wiring electrodes 25 on the surface of the Ni silicide film 23 of the SiC substrate 21 from which the graphite layer 24 is eliminated completely. This provides a strong adhesion between the wiring electrode 25 and the Ni silicide film 23, and prevents that the wiring electrode 25 peels off from the surface of the Ni silicide film 23.

In addition, because the sputtering for eliminating the graphite layer 24 and the forming of the wiring electrode are performed in the same chamber 1, it can prevent any adhesion of impurity particles onto the Ni silicide film 23. This also can increase the adhesion force between the wiring electrode 25 and the Ni silicide film 23.

Still further, according to the first embodiment of the present invention, the chamber 1 is vacuumed in the graphite layer elimination step, and the wiring electrode formation step is then performed while keeping the vacuum. Therefore it can be avoided to vacuum the chamber 1 at the wiring electrode formation step again when compared with the conventional fabrication method. This reduces the total number of fabrication steps and the fabrication time.

### Second Embodiment

A description will now be given of the SiC semiconductor device fabrication method according to the second embodiment of the present invention.

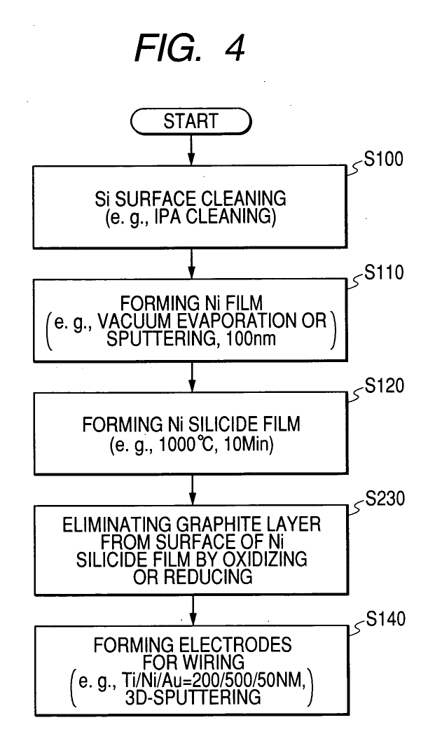

The first embodiment performs the argon gas sputtering of eliminating the graphite layer 24 from the Ni silicide film 23. On the contrary, the SiC semiconductor device fabrication method of the second embodiment performs a graphite layer eliminating step S230 shown in FIG. 4 by chemical reaction instead of the argon gas sputtering step S130. The graphite layer eliminating step of the second embodiment uses the wiring electrode formation apparatus shown in FIG. 1. FIG. 4 is a flow chart showing the fabrication process of the SiC semiconductor device according to the second embodiment.

Other steps S100, S110, S120, and S140 in the SiC semiconductor device fabrication method of the second embodiment are the same of those of the first embodiment. Therefore the explanation for those same steps S100, S110, S120, and S140 is omitted here.

First, the SiC substrate 21 is placed in the wiring electrode formation apparatus shown in FIG. 1. Oxidizing agent gas or reducing gas agent is introduced into the chamber 1 through the argon gas inlet 9 mounted on the wiring electrode formation apparatus shown in FIG. 1. Ozone gas or N₂O gas is used as oxidizing agent gas, and Hydrogen gas is used as reducing gas agent, for example.

The chamber 1 is then vacuumed by adjusting the amount of exhaust gas through the exhaust outlet 14 and halting the introduction of air and nitrogen gas through the air inlet 10 and the nitrogen gas inlet 11. According to necessity, the rotatable shutter 7 or the slidable shutter 8 covers each of the target metal electrodes 6a to 6e.

After this, although the fabrication condition is changed according to the magnitude of the pressure in the chamber 1, when oxidizing gas is used the thermal treatment is performed at the temperature, for example, 1,000° C. or below at which the oxidizing of the graphite layer 24 is performed, but at which oxidation of the SiC substrate 21 does not occur. On the contrary, although the fabrication condition is changed according to the magnitude of the pressure in the chamber 1, when reducing gas is used the thermal treatment is performed at the temperature, for example, 1,500° C. or below at which reduction of the graphite layer 24 is progressed, but at which etching of the SiC substrate 21 does not occur. The graphite layer 24 is thereby converted to CO₂ to be eliminated in oxidation, or converted to hydrocarbon such as methane to be eliminated in reduction. (step S230 shown in FIG. 4)

Following this, just like the manner of the first embodiment, the wiring electrode 25 is formed on the surface of the Ni silicide film 23, from which the graphite layer 24 has been eliminated, in order to fabricate the SiC semiconductor device. (step S140 shown in FIG. 4)

As described above, it is possible to eliminate the graphite layer 24 from the Ni silicide film 23 on the SiC substrate by performing oxidation or reduction. Thereby, the SiC semiconductor device fabrication method of the second embodiment has the same effect of that of the first embodiment.

### Third Embodiment

A description will now be given of the SiC semiconductor device fabrication method according to the third embodiment of the present invention. The SiC semiconductor device fabrication method according to the third embodiment performs heating step for evaporating the graphite layer 24.

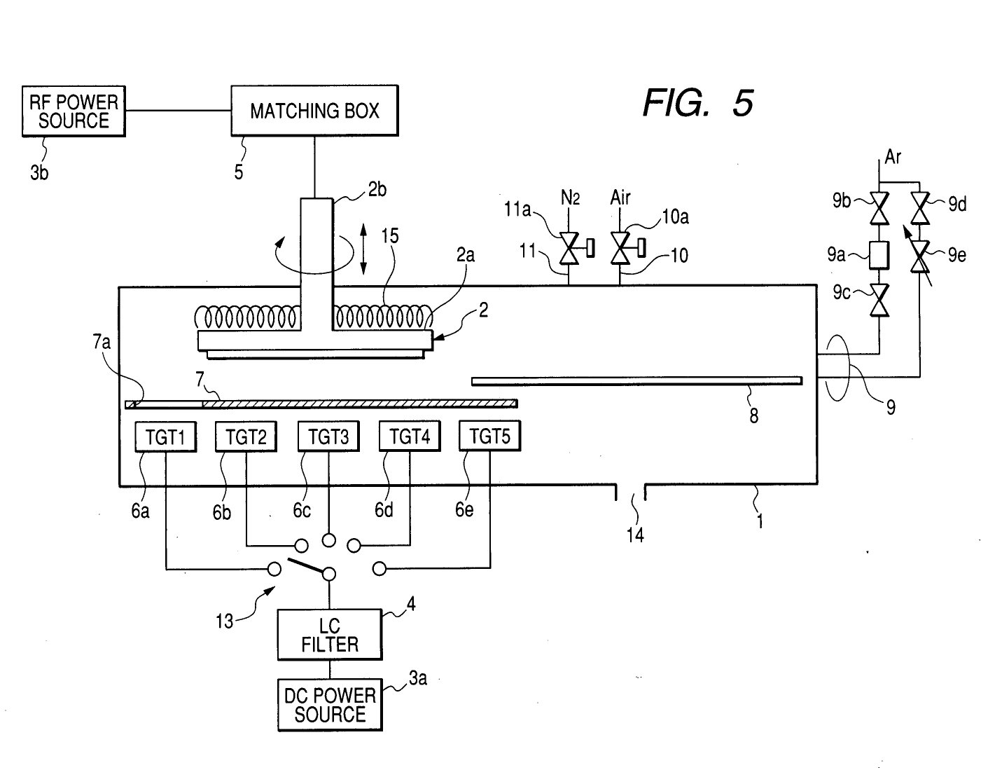

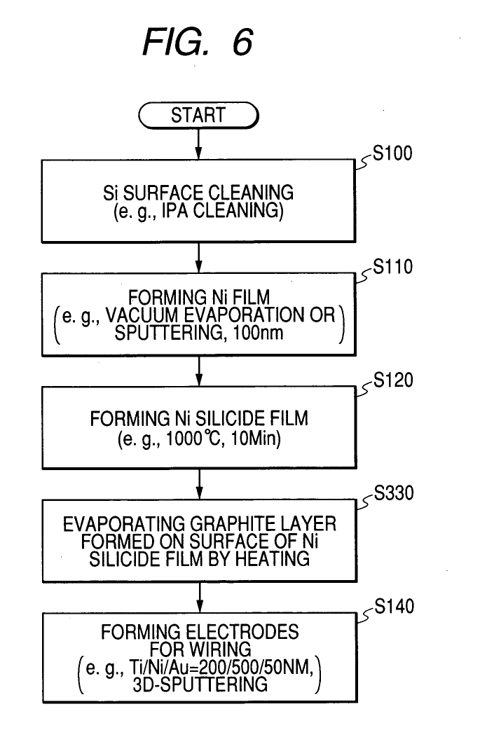

FIG. 5 is a schematic diagram showing another configuration of the electrode forming apparatus for use in the SiC semiconductor device fabrication method according to the third embodiment. FIG. 6 is a flow chart showing the fabrication process of the SiC semiconductor device of the third embodiment.

The electrode forming apparatus of the third embodiment has a heat element 15 composed of heating coil mounted on the substrate holder 2. The heat element 15 generates heat energy caused by the action of magnetic induction. Other components other than the heat element 15 are the same of those of the electrode forming apparatus of the first and second embodiments. The explanation of those same components is omitted here.

Because the third embodiment has the graphite eliminating step S330 that is different from the graphite eliminating steps S130 and S220 of the first and second embodiments, the explanation for the same steps S100, S110, S120, and S140 other than the graphite eliminating step S330 will be omitted.

First, the SiC substrate 21 is placed in the wiring electrode formation apparatus shown in FIG. 5. The chamber 1 is then vacuumed by controlling the amount of exhaust gas from the chamber 1 through the exhaust gas outlet 14 without introduction of nitrogen gas, air, and argon gas through the argon gas inlet 9, the air inlet 10, and the nitrogen gas inlet 11.

The Ni silicide film 23 is formed on the SiC substrate 21 after the formation of the Ni film 22 while performing the thermal treatment by the heating element 15 in order to evaporate graphite generated on the Ni silicide film 23. (step S330 shown in FIG. 6) As a result, the formation of the graphite layer can be avoided.

Following this, just like the manner of the first and second embodiments, the wiring electrode 25 is formed on the surface of the Ni silicide film 23 on which no graphite layer 24 is formed. (step S140 shown in FIG. 6)

As described above, it is possible to eliminate the graphite layer 24 from the Ni silicide film 23 on the SiC substrate or to prevent any graphite layer on the Ni silicide film 23 by performing heating control. Thereby, the SiC semiconductor device fabrication method of the third embodiment has the same effect of that of the first and second embodiments.

### Other Embodiments

Although the SiC semiconductor device fabrication method according to the first embodiment performs the graphite layer eliminating step by argon gas sputtering, the present invention is not limited by this manner.

For example, it is acceptable to eliminating the graphite layer 24 formed on the Ni silicide film 23 by reverse-sputtering such as oxygen gas sputtering capable of cleaning the surface of the Ni silicide film 23.

In the first to third embodiments, although the wiring electrode 25 is formed by sputtering, the present invention is not limited by this, for example, it is possible that a vacuum evaporation apparatus accommodates the SiC substrate 21 therein while keeping the vacuum state of the chamber 1 and the wiring electrode 25 is formed by vacuum evaporation.

### FEATURES AND EFFECTS OF THE PRESENT INVENTION

As described above in detail, the present invention provides the SiC semiconductor device fabrication method comprising following steps. A nickel (Ni) film is formed on a surface of a SiC substrate. A Ni silicide film is formed on the SiC substrate by performing thermal treatment. A graphite layer that is formed on the Ni silicide film is eliminated by the thermal treatment. A wiring electrode is formed on the Ni silicide film from which the graphite layer has been eliminated.

The present invention provides the improved method in which the wiring electrode is formed on the Ni silicide film after the graphite layer has been eliminated from the surface of the Ni silicide film. Therefore the method of the present invention prevents the deterioration of adhesion force between the Ni suicide film and the wiring electrode, and thereby prevents that the wiring electrode peels off from the surface of the Ni silicide film on the SiC substrate of the SiC semiconductor device.

According to the present invention, it is possible to eliminate the graphite layer from the Ni silicide film on the SiC substrate by sputtering. For instance, argon sputtering is used for eliminating the graphite layer.

Further, the wiring electrode can be formed in the wirng electrode formation apparatus continuously following the graphite layer eliminating step. Thereby, this prevents any adhesion of impurity particles onto the Ni silicide film 23. This can also increase the adhesion force between the wiring electrode and the Ni silicide film.

Still further, according to the present invention, it is possible to eliminate the graphite layer from the Ni silicide film by performing chemical oxidation with oxidizing gas. For example, the graphite layer is eliminated by performing chemical oxidation with one of ozone gas and N₂O gas so that the graphite layer is converted to CO₂ by chemical oxidation.

Moreover, according to the present invention, it is possible to eliminate the graphite layer from the Ni silicide film by performing chemical reduction with reduction gas. For example, the graphite layer is eliminated by performing chemical reduction with H₂ gas so that the graphite layer is converted to hydrocarbon gas by chemical reduction.

Still further, according to the present invention, it is possible to eliminate the graphite layer from the Ni silicide film by evaporating the graphite layer using heat energy generated in the thermal treatment of forming the Ni silicide film.

While specific embodiments of the present invention have been described in detail, it will be appreciated by those skilled in the art that various modifications and alternatives to those details could be developed in light of the overall teachings of the disclosure. Accordingly, the particular arrangements disclosed are meant to be illustrative only and not limited to the scope of the present invention which is to be given the full breadth of the following claims and all equivalent thereof.

What is claimed is:

1. A silicone carbide (SiC) semiconductor device fabrication method comprising, steps of:
forming a nickel (Ni) film on a surface of a SiC substrate;
forming a Ni silicide film on the SiC substrate by thermal treatment;
eliminating a graphite layer formed on a surface of the Ni silicide film during the thermal treatment; and
forming wiring electrode on the Ni silicide film from which the graphite layer has been eliminated.

2. The SiC semiconductor device fabrication method according to claim 1, wherein the graphite layer is eliminated by performing sputtering.

3. The SiC semiconductor device fabrication method according to claim 2, wherein the graphite layer is eliminated by performing argon gas sputtering in a wiring electrode forming apparatus, and
the wiring electrode is then formed in the wiring electrode forming apparatus.

4. The SiC semiconductor device fabrication method according to claim 1, wherein the graphite layer is eliminated by performing chemical oxidation with oxidizing gas.

5. The SiC semiconductor device fabrication method according to claim 4, wherein the graphite layer is eliminated by performing chemical oxidation with one of ozone gas and N₂O gas so that the graphite layer is converted to CO₂ by chemical oxidation.

6. The SiC semiconductor device fabrication method according to claim 1, wherein the graphite layer is eliminated by performing chemical reduction with reduction gas.

7. The SiC semiconductor device fabrication method according to claim 6, wherein the graphite layer is eliminated by performing chemical reduction with H₂ gas so that the graphite layer is converted to hydrocarbon gas by chemical reduction.

8. The SiC semiconductor device fabrication method according to claim 1, wherein the graphite layer is evaporated by the thermal treatment of forming the Ni silicide film on the SiC substrate.

9. The SiC semiconductor device fabrication method according to claim 2, wherein the sputtering is performed more than five minutes in order to eliminate the graphite layer completely from the Ni silicide film.

10. The SiC semiconductor device fabrication method according to claim 4, wherein the chemical oxidation is performed at not more than 1,000° C. with oxidizing gas so that the graphite layer is eliminated completely from the Ni silicide film, but the Ni silicide film is not eliminated.

11. The SiC semiconductor device fabrication method according to claim 6, wherein the chemical reduction is performed at not more than 1,500° C. with reduction gas so that the graphite layer is eliminated completely from the Ni suicide film, but the Ni silicide film is not eliminated.
